(19) United States
(12) Patent Application Publication
(10) Pub. No.: US 2024/0280649 A1
(43) Pub. Date: Aug. 22, 2024

(54) Imager of a Magnetic Field using Josephson Junctions

(71) Applicant: The United States of America, as represented by the Secretary of the Navy, San Diego, CA (US)

(72) Inventors: Marcio Calixto de Andrade, San Diego, CA (US); Lee Lemay, San Diego, CA (US)

(21) Appl. No.: 18/172,489

(22) Filed: Feb. 22, 2023

(51) Int. Cl. G01R 33/035

(52) U.S. Cl. CPC G01R 33/0354

(57) ABSTRACT

An imager of a magnetic field includes a sensor array and a display. The sensor array includes sensor pixels, which each include at least one Josephson junction for generating an electrical signal responsive to a magnetic flux of the magnetic field through the sensor pixel. The display is coupled to the sensor array for displaying, for each of the sensor pixels, a respective strength from the electrical signal of the magnetic flux through the sensor pixel.

### FEDERALLY SPONSORED RESEARCH AND DEVELOPMENT

The United States Government has ownership rights in this invention. Licensing and technical inquiries may be directed to the Office of Research and Technical Applications, Naval Information Warfare Center Pacific, Code 72120, San Diego, CA, 92152; voice (619) 553-5118; NIWC_Pacific_T2@us.navy.mil. Reference Navy Case Number 107419.

### BACKGROUND OF THE INVENTION

Magnetic microscopes usually employ a single sensing tip scanned over the probed area to detect the local magnetic field. Due to the moving probe, magnetic microscopes typically operate only at low frequencies.

Magnetic pixels (maxels) each include an active magnetized material generating a local magnetic field that interacts with a probed surface. Generally, the local magnetic field from each maxel affects some property of the probed surface, and a separate detector detects this changed property of the probed surface.

### SUMMARY OF THE INVENTION

An imager of a magnetic field includes a sensor array and a display. The sensor array includes sensor pixels, which each include at least one Josephson junction for generating an electrical signal responsive to a magnetic flux of the magnetic field through the sensor pixel. The display is coupled to the sensor array for displaying, for each of the sensor pixels, a respective strength from the electrical signal of the magnetic flux through the sensor pixel.

### BRIEF DESCRIPTION OF DRAWINGS

Throughout the several views, like elements are referenced using like references. The elements in the figures are not drawn to scale and some dimensions are exaggerated for clarity.

FIG. 1 is a block diagram of an imager of a magnetic field including a sensor array of sensor pixels and a display in accordance with an embodiment of the invention.

FIG. 2A-E are block diagrams of examples of each sensor pixel in the sensor array of FIG. 1.

### DETAILED DESCRIPTION

The disclosed systems below may be described generally, as well as in terms of specific examples and/or specific embodiments. For instances where references are made to detailed examples and/or embodiments, it should be appreciated that any of the underlying principles described are not to be limited to a single embodiment, but may be expanded for use with any of the other systems and methods described herein as will be understood by one of ordinary skill in the art unless otherwise stated specifically.

Embodiments of the invention capture a magnetic image of an object with high spatial resolution. The disclosed sensor pixels do not contain any magnetic material and passively detect an image of a magnetic field emanating from an object without any scanning. The fundamental working principle of the sensor pixels is the quantum nature of a superconducting loop interconnecting one or more Josephson junctions. The magnetic flux of a magnetic field passing through such a superconducting loop is quantized in units of the flux quantum Φ₀, where Φ₀=h/2e, with h being Planck's constant, and 2e is the charge of the superconducting Cooper pair. The sensor pixels employ the unique properties of such loops of a superconducting material. Embodiments of the invention capture a magnetic image of an object with at a microscopic scale with a submicron spatial resolution and detect the magnetic image with a high sensitivity of approximately femto-Tesla within a broad frequency band from DC to GHz.

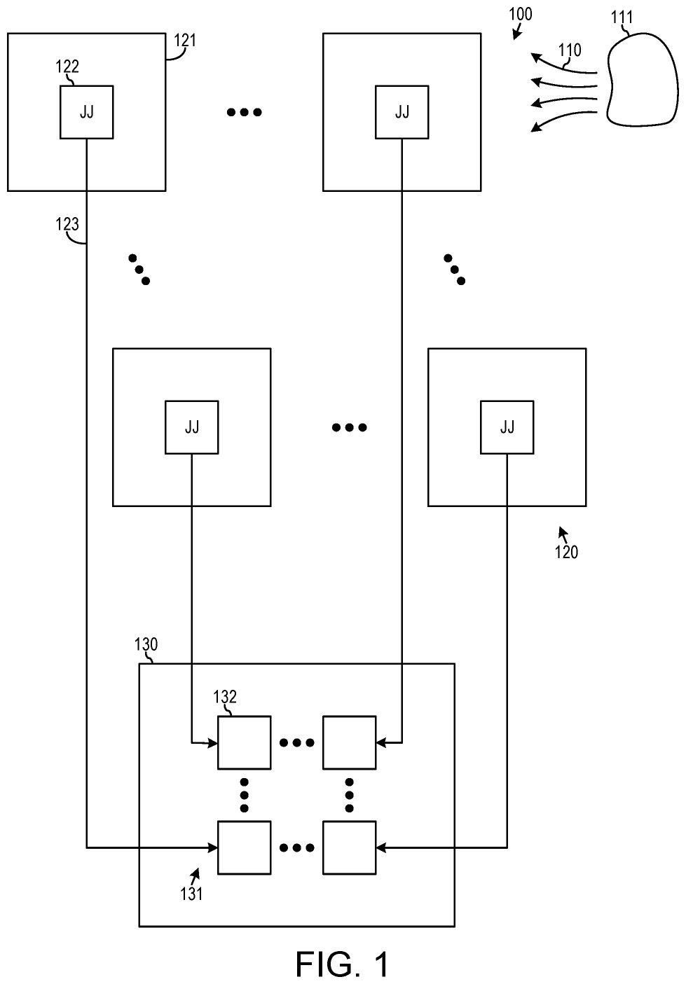

FIG. 1 is a block diagram of an imager 100 of a magnetic field 110 including a sensor array 120 of sensor pixels and a display 130 in accordance with an embodiment of the invention.

The sensor array 120 includes the sensor pixels, such as sensor pixel 121, and each sensor pixel 121 in the sensor array 120 includes at least one Josephson junction 122 for generating an electrical signal 123 responsive to a magnetic flux of the magnetic field 110 through the sensor pixel 121. The display 130 is coupled to the sensor array 120 for displaying, for each sensor pixel 121 in the sensor array 120, a respective strength from the electrical signal 123 of the magnetic flux through the sensor pixel 121.

In one embodiment, the display 130 includes an indicator array 131 of indicator regions, such as indicator region 132. Each indicator region 132 corresponds to a respective sensor pixel 121 in the sensor array 120. Each indicator region 132 displays the respective strength from the electrical signal 123 of the magnetic flux of the magnetic field 110 through the respective sensor pixel 121. For example, the respective strength of the magnetic flux is displayed with a light intensity, a color spectrum, or an active portion of a bar graph.

In one embodiment, the indicator array 131 and the sensor array 120 are each two dimensional with the indicator array 131 being a magnified scaling of the sensor array 120, and each indicator region 132 is the magnified scaling of the respective sensor pixel 121. The indicator region 132 displays a temporal variation of the respective strength from the electrical signal 123 of the magnetic flux of the magnetic field 110 through the respective sensor pixel 121.

In another embodiment, the sensor array 120 is distributed on the surface of a three dimensional structure, such as a diamond structure. The indicator array 131 mimics the three dimensional structure or is a flattening of the three dimensional structure.

The sensor pixels in the sensor array 120 concurrently sense the respective strength of the magnetic flux of the magnetic field 110 at each of the sensor pixels in the sensor array 120. Each sensor pixel 121 in the sensor array 120 independently senses the respective strength of the magnetic flux through the sensor pixel 121. The display 130 displays a spatial image of a temporal variation of the respective strength of the magnetic flux through each of the sensor pixels in the sensor array 120. The display 130 displays the spatial image of the magnetic field 110 emanating from an object 111 nearby the imager 100 or from an environment around the imager 100. Typically, the magnetic field 110 is a near field from an object 111 and hence not a propagating electromagnetic field. The display 130 displays the spatial image of the magnetic field 110 emanating from an object 111 nearby the imager 100 without any scanning of the sensor array 120 relative to the object 111. However, it will be appreciated that the addition of scanning increases the sensing extent beyond than of just the sensor array 120.

In one embodiment, the display 130 displays the spatial image with submicron spatial resolution of a temporal variation from DC to GHz of the respective strength of the magnetic flux through each of the sensor pixels in the sensor array 120.

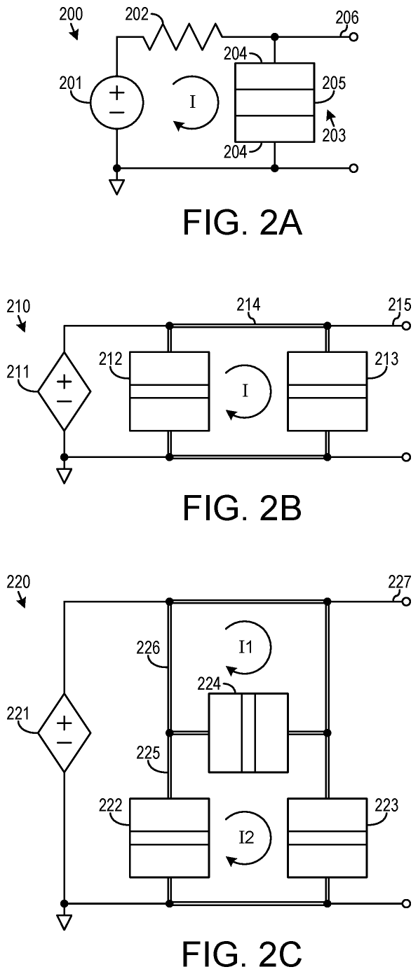

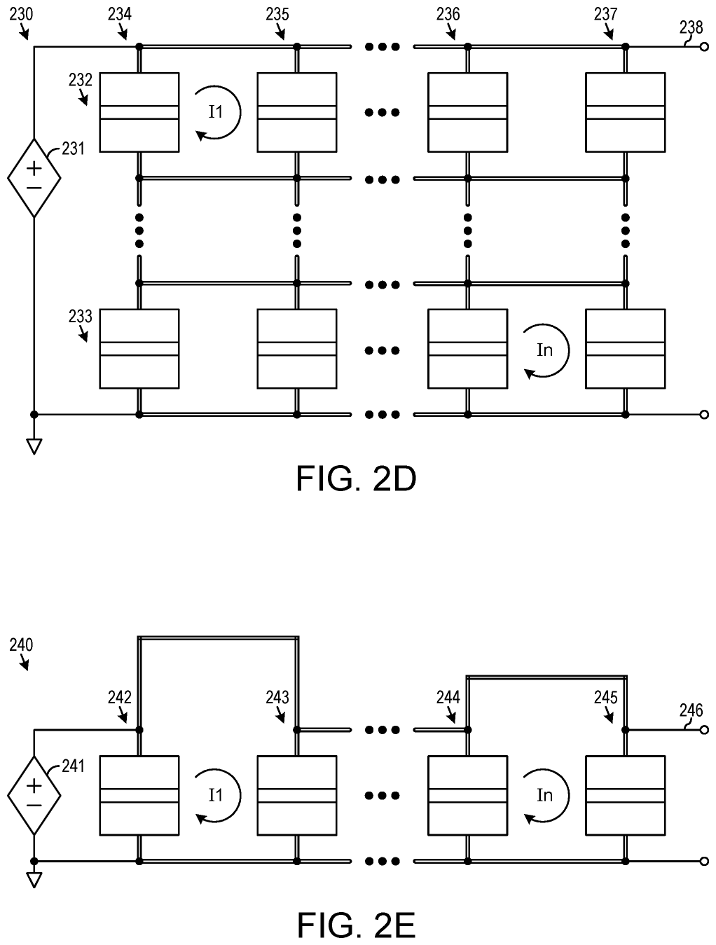

FIG. 2A is a block diagram of an example 200 of each sensor pixel, such as sensor pixel 121, in the sensor array 120 of FIG. 1. The example 200 sensor pixel includes a voltage source 201, a resistor 202, and a single Josephson junction 203.

The Josephson junction 203 has outer regions 204 of a superconducting material sandwiching a region 205 of another material, which is an insulator material, a metal material, or another superconducting material differing from the superconducting material of outer regions 204. For example, the different superconducting material of region 205 is the superconducting material of regions 204 modified by bombardment with a focused ion beam to change its properties.

The Josephson junction 203 has a critical current. The critical current of the Josephson junction 203 is the maximum current that the device can carry before transitioning from the superconducting state to the normal state. Below the critical current, the Josephson junction 203 is superconducting with zero resistance and hence the electrical signal 206 is zero volts. Magnetic flux, which couples through the loop formed around the voltage source 201, the resistor 202, and the Josephson junction 203, increases and decreases the current through Josephson junction 203. Thus, when the voltage source 201 and the resistor 202 are selected to bias approximately the critical current through the Josephson junction 203, changes in the magnetic flux at the example 200 sensor pixel generate a non-zero voltage at electrical signal 206. The dissipation within resistor 202 limits detection to changing magnetic flux, unlike additional examples of sensor pixels discussed below that detect the static magnetic flux of a magnetic field.

In summary, the electrical signal 206 of Josephson junction 203 in example 200 sensor pixel depends upon a deviation of a junction current through the Josephson junction 203 from the critical current of the Josephson junction 203. The junction current through the Josephson junction 203 depends upon the respective strength of the magnetic flux through the example 200 sensor pixel.

The Josephson junction 203 is an extremely sensitive magnetic flux detector. The Josephson junction 203 helps detect minute changes in the magnetic field. The Josephson junction 203 is fabricated utilizing microfabrication techniques allowing for very small dimensions. As discussed further below, a single sensor pixel 121 of FIG. 1 can contain many thousands of Josephson junctions connected in parallel and/or in series within an array. The number of Josephson junctions in each sensor pixel is established by the resolving power required from each sensor pixel. The sensitive detection of magnetic flux has applications in the medical field, mineralogy, magnetometry, and others.

FIG. 2B is a block diagram of an example 210 of each sensor pixel, such as sensor pixel 121, in the sensor array 120 of FIG. 1. The example 210 sensor pixel includes a current source 211, two Josephson junctions 212 and 213, and a single loop 214 of the superconducting material.

The loop 214 of superconducting material is shown in FIG. 2B with doubled lines, but also includes the outer regions of Josephson junctions 212 and 213. Each Josephson junction 212 or 213 interrupts the loop 214 of the superconducting material with another material, which is an insulator material, a metal material, or another superconducting material differing from the superconducting material of the loop 214. The loop 214 of superconducting material interconnects the Josephson junctions 212 and 213. The current source 211 biases both Josephson junctions 212 and 213 near their critical currents. The junction current through each Josephson junction 212 or 213 depends upon the respective strength of the magnetic flux passing through the loop 214 of the superconducting material. The electrical signal 215 specifies the respective strength of the magnetic flux of the magnetic field passing through the loop 214.

In one embodiment, the two Josephson junctions 212 and 213 and the single loop 214 of superconducting material interconnecting these Josephson junctions 212 and 213 form a superconducting quantum interference device (SQUID).

FIG. 2C is a block diagram of an example 220 of each sensor pixel, such as sensor pixel 121, in the sensor array 120 of FIG. 1. The example 220 sensor pixel includes a current source 221, three Josephson junctions 222, 223, and 224, and two loops 225 and 226 of the superconducting material. The two loops 225 and 226 typically have different perimeter lengths and enclose differing amounts of area. The electrical signal 227 specifies the respective strength of the magnetic flux of the magnetic field passing through the loops 225 and 226.

In one embodiment, the two loops 225 and 226 of superconducting material interconnect the three Josephson junctions 222, 223, and 224 to form a bisected superconducting quantum interference device (bi-SQUID). The electrical signal 227 of the bi-SQUID of FIG. 2C has improved linearity of dependence upon the magnetic flux as compared with the electrical signal 215 of the SQUID of FIG. 2B.

FIG. 2D is a block diagram of an example 230 of each sensor pixel, such as sensor pixel 121, in the sensor array 120 of FIG. 1. The example 230 sensor pixel includes a current source 231, rows 232 through 233 and columns 234 and 235 through 236 and 237 of Josephson junctions and loops of the superconducting material.

In one embodiment, the loops of superconducting material have a same size and interconnect the Josephson junctions to form a superconducting quantum interference device (SQUID) array. The number of SQUIDs in the array of a single sensor pixel is established by the frequency and power the example 230 sensor pixel is designed to resolve. The electrical signal 238 specifies the respective strength of the magnetic flux of the magnetic field passing through the SQUID array.

FIG. 2E is a block diagram of an example 240 of each sensor pixel, such as sensor pixel 121, in the sensor array 120 of FIG. 1. The example 240 sensor pixel includes a current source 241 and columns 242 and 243 through 244 and 245 of Josephson junctions and loops of the superconducting material.

In one embodiment, the loops of superconducting material have a variety of sizes and interconnect the Josephson junctions to form a Superconducting Quantum Interference Filter (SQIF). It will be appreciated that the SQIF can include multiple rows connected in series similar to the rows 232 through 233 of FIG. 2D. The electrical signal 246 specifies the respective strength of the magnetic flux of the magnetic field passing through the SQIF.

From the above description of an Imager of a Magnetic Field using Josephson Junctions, it is manifest that various techniques may be used for implementing the concepts of magnetic field imager 100 without departing from the scope of the claims. The described embodiments are to be considered in all respects as illustrative and not restrictive. The magnetic field imager 100 disclosed herein may be practiced in the absence of any element that is not specifically claimed and/or disclosed herein. It should also be understood that magnetic field imager 100 is not limited to the particular embodiments described herein, but is capable of many embodiments without departing from the scope of the claims.

We claim:

1. An imager of a magnetic field comprising:
a sensor array of a plurality of sensor pixels, wherein each one of the sensor pixels in the sensor array includes at least one Josephson junction for generating an electrical signal responsive to a magnetic flux of the magnetic field through the one of the sensor pixels; and
a display coupled to the sensor array for displaying, for each one of the sensor pixels, a respective strength from the electrical signal of the magnetic flux through the one of the sensor pixels.

2. The imager of claim 1, wherein the sensor pixels in the sensor array concurrently sense the respective strength of the magnetic flux of the magnetic field at each of the sensor pixels.

3. The imager of claim 1, wherein the display displays a spatial image of a temporal variation of the respective strength of the magnetic flux through each of the sensor pixels in the sensor array.

4. The imager of claim 3, wherein the display displays the spatial image of the magnetic field emanating from an object nearby the imager or from an environment around the imager.

5. The imager of claim 4, wherein the display displays the spatial image of the magnetic field emanating from the object nearby the imager without any scanning of the sensor array relative to the object.

6. The imager of claim 1, wherein the display displays a spatial image of the magnetic field emanating from an object nearby the imager or from an environment around the imager.

7. The imager of claim 6, wherein the display displays the spatial image with submicron spatial resolution of a temporal variation from DC to GHz of the respective strength of the magnetic flux through each of the sensor pixels in the sensor array.

8. The imager of claim 1, wherein the display displays a spatial image of the magnetic field emanating from an object nearby the imager without any scanning of the sensor array relative to the object.

9. The imager of claim 1, wherein the display includes an indicator array of a plurality of indicator regions, each of the indicator regions corresponding to a respective one of the sensor pixels, each of the indicator regions for displaying the respective strength of the magnetic flux through the respective one of the sensor pixels.

10. The imager of claim 9, wherein the indicator array and the sensor array are each two-dimensional with the indicator array being a magnified scaling of the sensor array and with each of the indicator regions being the magnified scaling of the respective one of the sensor pixels.

11. The imager of claim 9, wherein each of the indicator regions is for displaying a temporal variation of the respective strength of the magnetic flux through the respective one of the sensor pixels.

12. The imager of claim 1, wherein the electrical signal of said at least one Josephson junction in each one of the sensor pixels depends upon a deviation of a junction current from a critical current, and the junction current through said at least one Josephson junction depends upon the respective strength of the magnetic flux through the one of the sensor pixels.

13. The imager of claim 12, wherein each of the sensor pixels in the sensor array further includes at least one loop of superconducting material interconnecting said at least one Josephson junction, and the junction current through each of said at least one Josephson junction depends upon the respective strength of the magnetic flux passing through said at least one loop.

14. The imager of claim 13, wherein each of said at least one Josephson junction interrupts one of said at least one loop of the superconducting material with another material, which is an insulator material, a metal material, or another superconducting material differing from the superconducting material of said at least one loop.

15. The imager of claim 1, wherein each of the sensor pixels in the sensor array further includes at least one loop of superconducting material interconnecting said at least one Josephson junction, with the electrical signal for specifying the respective strength of the magnetic flux of the magnetic field passing through said at least one loop.

16. The imager of claim 1, wherein each of the sensor pixels in the sensor array includes said at least one Josephson junction, which is a single Josephson junction.

17. The imager of claim 1, wherein each of the sensor pixels in the sensor array includes said at least one Josephson junction, which is two Josephson junctions, and a loop of superconducting material interconnecting the two Josephson junctions to form a superconducting quantum interference device (SQUID).

18. The imager of claim 1, wherein each of the sensor pixels in the sensor array includes said at least one Josephson junction, which is three Josephson junctions, and two loops of superconducting material interconnecting the three Josephson junctions to form a superconducting quantum interference device (bi-SQUID).

19. The imager of claim 1, wherein each of the sensor pixels in the sensor array includes said at least one Josephson junction, which is a plurality of Josephson junctions, and a plurality of loops of superconducting material of a same size interconnecting the Josephson junctions to form a superconducting quantum interference device (SQUID) array.

20. The imager of claim 1, wherein each of the sensor pixels in the sensor array includes said at least one Josephson junction, which is a plurality of Josephson junctions, and a plurality of loops of superconducting material of a variety of sizes interconnecting the Josephson junctions to form a Superconducting Quantum Interference Filter (SQIF).
